(19) United States
(12) Patent Application Publication
(10) Pub. No.: US 2025/0393374 A1
(43) Pub. Date: Dec. 25, 2025

(54) LIGHT EMITTING DEVICE

(71) Applicant: AUO Corporation, Hsinchu City (TW)

(72) Inventor: I-Hsun HSIEH, Hsinchu City (TW)

(21) Appl. No.: 19/203,231

(22) Filed: May 9, 2025

(30) Foreign Application Priority Data
Jun. 21, 2024 (TW) 113123227

(51) Int. Cl. H10H 29/851; H10H 29/856

(52) U.S. Cl. CPC H10H 29/8514; H10H 29/8511; H10H 29/856

(57) ABSTRACT

A light emitting device includes a substrate and a plurality of light emitting components. The substrate has a plurality of accommodation recesses. The light emitting components are disposed in the accommodation recesses. The light emitting components include a die, a wavelength converting colloid, and a rooflike optic component apiece. The die can emit light and are disposed in accommodation recess. The die is perpendicularly projected onto the substrate to form a first orthogonal projection region. The wavelength converting colloid fills the accommodation recess and covers the die. The wavelength converting colloid has a convex surface. The rooflike optic component is disposed on the convex surface. The rooflike optic component is perpendicularly projected onto the substrate to form a second orthogonal projection region. The area of the first orthogonal projection region is less than the area of the second orthogonal projection region.

### CROSS-REFERENCE TO RELATED APPLICATION

This application claims priority to Taiwan Application Serial Number 113123227, filed Jun. 21, 2024, which is herein incorporated by reference in its entirety.

### BACKGROUND

### Technical Field

The present disclosure relates to a light emitting device. More particularly, the present disclosure relates to a light emitting device including a wavelength converting colloid.

### Description of Related Art

A backlight module used in a conventional Liquid Crystal Display (LCD) employs a plurality of Light Emitting Diode Packages (referred to hereafter as “LED”) as a light source. A common LED usually has very high optic directionality, so that the previous LEDs emit the light non-uniformly. Hence, a conventional backlight module employs a plurality of diffusers to uniform the light emitted from the LEDs, so that the backlight module can uniformly emit light, thereby preserving or improving the image quality displayed by the LCD.

### SUMMARY

The disclosure according to at least one embodiment provides a light emitting device which uses a rooflike optic component to facilitate uniform emission of light.

The light emitting device according to at least one embodiment includes a substrate and a plurality of light emitting components. The substrate has a surface and a plurality of accommodation recesses in the surface. The light emitting components are disposed in the accommodation recesses. Each of the light emitting components includes a die, a wavelength converting colloid, and a rooflike optic component. The die is disposed on the substrate and located in one of the accommodation recesses. The die is perpendicularly projected onto the substrate to form a first orthogonal projection region and used for emitting light. The wavelength converting colloid disposed on the substrate fills one of the accommodation recesses and covers the die. The wavelength converting colloid has a convex surface, where the rooflike optic component is disposed on the convex surface of the wavelength converting colloid and overlaps the die. The rooflike optic component is perpendicularly projected onto the substrate to form a second orthogonal projection region. The size of the first orthogonal projection region of the die is smaller than the size of the second orthogonal projection region of the rooflike optic component.

Based on the above, the previous rooflike optic component can attenuate a large amount of light emitted from the upper surface of the die, thereby helping the light emitting device to emit light uniformly. Therefore, the above light emitting device of the disclosure can be employed for a backlight module used in LCD, so as to preserve or improve the image quality displayed by LCD.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1A is a top view of a light emitting device according to at least one embodiment of this disclosure.

FIG. 1B is a cross-sectional view along line 1B-1B of FIG. 1A.

FIG. 2A is a top view of a light emitting device according to another embodiment of this disclosure.

FIG. 2B is a cross-sectional view along line 2B-2B of FIG. 2A.

FIG. 3A to FIG. 3C are cross-sectional views of a method of manufacturing a light emitting device according to at least one embodiment of this disclosure.

FIG. 3D and FIG. 3E depict rectangular candela distribution plots by simulating the light emitting device in FIG. 1B.

FIG. 4 is a top view of a light emitting device according to another embodiment of this disclosure.

FIG. 5 is a top view of a light emitting device according to another embodiment of this disclosure.

### DETAILED DESCRIPTION

In the following description, in order to clearly present the technical features of the present disclosure, the dimensions (such as length, width, thickness, and depth) of elements (such as layers, films, substrates, and areas) in the drawings will be enlarged in unusual proportions, and the quantity of some elements will be reduced. Accordingly, the description and explanation of the following embodiments are not limited to the quantity, sizes and shapes of the elements presented in the drawings, but should cover the sizes, shapes, and deviations of the two due to actual manufacturing processes and/or tolerances. For example, the flat surface shown in the drawings may have rough and/or non-linear characteristics, and the acute angle shown in the drawings may be round. Therefore, the elements presented in the drawings in this case which are mainly for illustration are intended neither to accurately depict the actual shape of the elements nor to limit the scope of patent applications in this case.

Moreover, the words, such as “about”, “approximately”, or “substantially”, appearing in the present disclosure not only cover the clearly stated values and ranges, but also include permissible deviation ranges as understood by those with ordinary knowledge in the technical field of the invention. The permissible deviation range can be caused by the error generated during the measurement, where the error is caused by such as the limitation of the measurement system or the process conditions. In addition, “about” may be expressed within one or more standard deviations of the values, such as within ±30%, ±20%, ±10%, or ±5%. The word “about”, “approximately” or “substantially” appearing in this text can choose an acceptable.

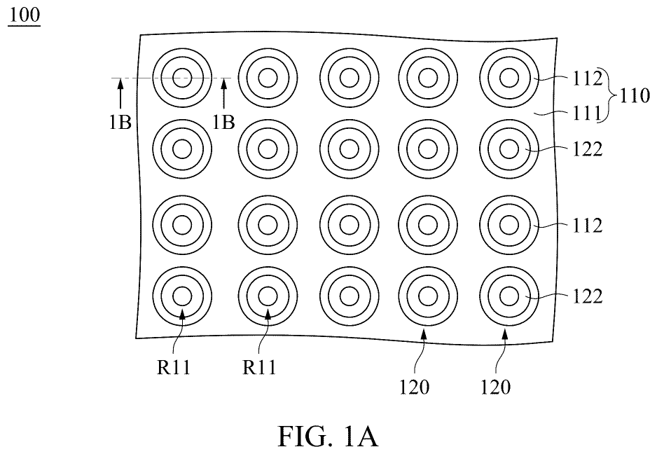

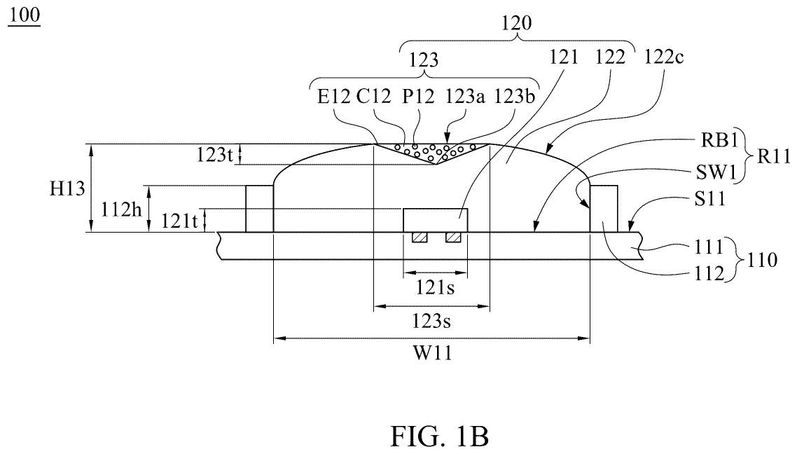

FIG. 1A is a top view of a light emitting device according to at least one embodiment of this disclosure, and FIG. 1B is a cross-sectional view along line 1B-1B of FIG. 1A. Referring to FIG. 1A and FIG. 1B, a light emitting device 100 includes a substrate 110 and a plurality of light emitting components 120. The substrate 110 has a surface S11 and a plurality of accommodation recesses R11 in the surface S11, where these light emitting components 120 are disposed in the accommodation recesses R11.

In the embodiment, the substrate 110 includes a supporting board 111 and a plurality of fences 112, where the supporting board 111 has the surface S11, and the fences 112 are disposed on the surface S11. Each of the fences 112 surrounds an accommodation space on the surface S11, so that the fences 112 and the supporting board 111 define the accommodation recesses R11. The surface S11 and each of the fences 112 form the bottom RB1 and the sidewall SW1 of one of the accommodation recesses R11 respectively. Each of the light emitting components 120 is disposed on the bottom RB1 of one of the accommodation recesses R11 and is surrounded by one of the fences 112.

In the embodiment, the width W11 of each of the accommodation recesses R11 may range between 2800 μm and 5500 μm. Each of the fence 112 may be in the shape of a circular ring (as shown in FIG. 1A), while the width W11 may be the inner diameter of a single fence 112. The height 112h of each of the fences 112 can range between 200 μm and 600 μm. In addition, each of the fences 112 may also be in the shape of a frame (i.e., rectangular ring) or an elliptical ring, so the fence 112 depicted in FIG. 1A does not limit the real shape of the fences 112.

The supporting board 111 is a wiring board and has at least one wiring layer (not shown). Specifically, when there is only one wiring layer in the supporting board 111, the surface S11 will expose at least part of the wiring layer. When there are multiple wiring layers in the supporting board 111, the surface S11 will expose at least part of one of the wiring layers. Moreover, the wiring layer appearing from the surface S11 includes at least one pad, where the part of the wiring layer is exposed by the surface S11 is the previous pads, and the light emitting components 120 are electrically connected to the pads, so that the light emitting components 120 are able to electrically connected to the supporting board 111.

The light emitting components 120 include a die 121 and a wavelength converting colloid 122 apiece. The dies 121 and the wavelength converting colloids 122 are disposed on the substrate 110. Taking FIG. 1B for example, the dies 121 and the wavelength converting colloids 122 are disposed on the surface S11 of the supporting board 111, while the die 121 and the wavelength converting colloid 122 of each light emitting component 120 are located in one of the accommodation recesses R11. The wavelength converting colloid 122 fills the accommodation recesses R11, so the width W11 of the accommodation recesses R11 is substantially equal to the width of the wavelength converting colloid 122.

The die 121 may be a LED, such as a micro-LED (μLED) or a mini-LED, so that the die 121 can emit light. Hence, the light emitting device 100 can emit light, in which the die 121 can emit blue light or ultraviolet (UV) light. That is, the die 121 may be a blue LED or a UV LED.

The die 121 may be a horizontal LED, that is, the electrodes of the die 121 are located at the same side of the die 121, as shown in FIG. 1B. In the embodiment, the die 121 is disposed on the substrate 110 by flip chip and connected to the pads of the supporting board 111, so that the die 121 is electrically connected to the supporting board 111. Accordingly, an external power supply can supply electricity to the die 121 via the supporting board 111, so the light emitting components 120 can emit light.

The dies 121 have a thickness 121t and a length 121s apiece. In the embodiment, the thickness 121t may range between 30 μm and 300 μm, such as between 80 μm and 170 μm. The length 121s may range between 30 μm and 3000 μm, such as between 300 μm and 1200 μm. Since the height 112h of the fence 112 may range between 200 μm and 600 μm, and the thickness 121t of the die 121 may range between 30 μm and 300 μm, the height 112h can greater than the thickness 121t, that is, the fences 112 can protrude from the upper surface of the die 121, as shown in FIG. 1B.

The wavelength converting colloid 122 fills one of the accommodation recesses R11 and covers the die 121, where the wavelength converting colloid 122 has a convex surface 122c. The wavelength converting colloid 122 can contain gel and wavelength converting materials. The wavelength converting materials are distributed in the gel. The gel may be silicone, and the wavelength converting materials are at least one of phosphor powders and Quantum Do (QD) materials, for example. The wavelength converting colloid 122 can absorb the light from the die 121 and convert its wavelength.

For example, the die 121 can emit blue light, while the wavelength converting colloid 122 can absorb blue light and convert the part of the blue light into yellow light. Accordingly, the light emitting components 120 can emit white light. Alternatively, the light emitting components 120 may include multiple kinds of wavelength converting colloids 122 which contain multiple kinds of QD materials, so that the wavelength converting colloids 122 can convert the light (i.e., blue light) emitted from the die 121 into various color light, such as red light and green light. As a result, the light emitting components 120 can emit various color light, such as red light, green light, and blue light. In addition, in another embodiment, the die 121 also can emit invisible light, such as UV light, and the wavelength converting colloids 122 can convert UV light into red light, green light, and blue light.

When the light emitting components 120 emit white light, the light emitting device 100 can be made into a light source module, such as a backlight module used in LCD. When the light emitting components 120 emit various color light, such as red light, green light, and blue light, the light emitting device 100 can be directly made into a self-emitting display, such as outer color LED display. In addition, the light emitting components 120 also can emit monochromatic light (such as red light), so that the light emitting device 100 can be directly made into an electronic signage board, such as electronic advertising billboard.

The light emitting components 120 further include a rooflike optic component 123 apiece, in which the rooflike optic components 123 are disposed on the convex surfaces 122c of the wavelength converting colloids 122. The rooflike optic components 123 have a maximum thickness 123t and a length 123s apiece. The maximum thickness 123t can range between 20 μm and 200 μm, such as between 50 μm and 100 μm. The length 123s can range between 1600 μm and 3200 μm, where the length 123s of the rooflike optic component 123 can be greater than the length 121s (which may range between 30 μm and 3000 μm) of the die 121. In addition, the ratio of the width of the wavelength converting colloid 122 (i.e., the width W11) to the length 123s of the rooflike optic component 123 can be from 1.72 to 3.5.

The rooflike optic components 123 and the dies 121 overlap. Specifically, the die 121 is perpendicularly projected onto the surface S11 (i.e., bottom RB1) of the substrate 110 to form a first orthogonal projection region, where the length 121s depicted in FIG. 1B can be regarded as the first orthogonal projection region roughly. The rooflike optic component 123 is perpendicularly projected onto the surface S11 (i.e., bottom RB1) of the substrate 110 to form a second orthogonal projection region, where the length 123s depicted in FIG. 1B can be regarded as the second orthogonal projection region roughly.

As seen in FIG. 1A and FIG. 1B, the length 121s is less than the length 123s, and the size (e.g., area) of the first orthogonal projection region of the die 121 is smaller than the size (e.g., area) of the second orthogonal projection region of the rooflike optic component 123. Moreover, in the light emitting component 120 as shown in FIG. 1B, the length 121s falls within the length 123s completely, so that the first orthogonal projection region falls within the second orthogonal projection region completely. Hence, in one single light emitting component 120, the rooflike optic component 123 protrudes from the side of the die 121, as shown in FIG. 1B.

The rooflike optic component 123 includes a pyramid C12 and a plurality of diffusing particles P12, where the diffusing particles P12 are distributed in the pyramid C12. The pyramid C12 is made of silicone, while the diffusing particles P12 can be titanium dioxide particles. In addition, the rooflike optic component 123 can be made by molding. In the embodiment, the pyramid C12 may be in the shape of a cone. In another embodiment, the pyramid C12 may be in the shape of a regular polygonal base pyramid, such as square pyramid.

The pyramid C12 has an apex 123b and a base 123a opposite to the apex 123b, where the base 123a has an edge E12, and the distance between the pyramid C12 and the surface S11 increases gradually from the apex 123b to the edge E12, as shown in FIG. 1B. Hence, the pyramid C12 further has a side (not labeled) between the apex 123b and the base 123a, where an included angle of the pyramid C12 between the side and the base 123a is less than 90°, so that the pyramid C12 can reflect the light from the die 121. As a result, the light emitted from the die 121 can travel in all directions substantially, thereby helping the light emitting device 100 to emit light uniformly. In addition, the distance H13 between the base 123a and the surface S11 may range between 800 μm and 2000 μm.

The rooflike optic component 123 has a high reflectivity. For example, the reflectivity of the rooflike optic component 123 at a wavelength of 480 nm ranges between 70% and 99%. Hence, the rooflike optic component 123 can reflect the light emitted from the die 121, especially reflect blue light, so as to cause the wavelength converting colloid 122 to convert a large amount of light. In the embodiment as shown in FIG. 1B, the rooflike optic component 123 is located directly above the die 121 and can attenuate a large amount of light from the upper surface of the die 121. As a result, the rooflike optic component 123 can help the light emitting device 100 to emit light uniformly, so as to preserve or improve the image quality displayed by the LCD.

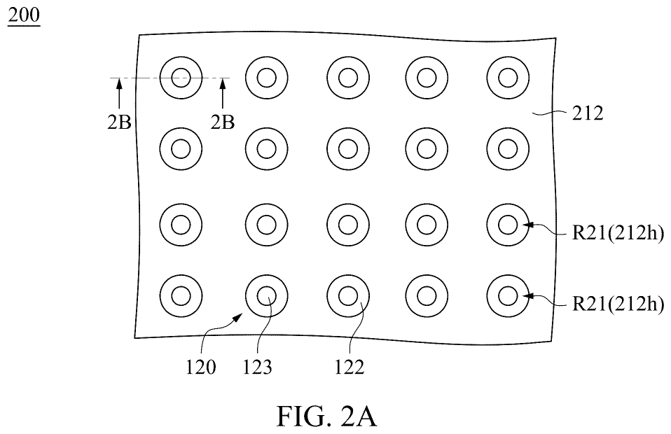

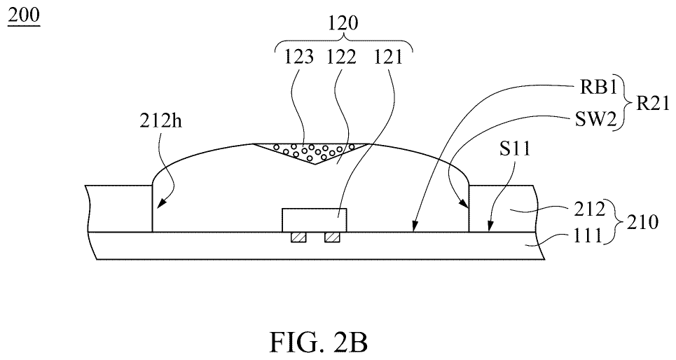

FIG. 2A is a top view of a light emitting device according to another embodiment of this disclosure, and FIG. 2B is a cross-sectional view along line 2B-2B of FIG. 2A. Referring to FIG. 2A and FIG. 2B, the light emitting device 200 of the present embodiment is similar to the light emitting device 100 of the previous embodiment, where the light emitting devices 100 and 200 have the same effectiveness and includes the same elements, such the supporting board 111 and the light emitting components 120. The following description will mainly describe the differences between the light emitting devices 100 and 200, while the same features of both will not be repeated basically.

The light emitting device 200 includes a substrate 210, while the substrate 210 also includes a supporting board 111. The light emitting components 120 are disposed on the supporting board 111 of the substrate 210 and electrically connected to the supporting board 111. In contrast to the previous substrate 110, the substrate 210 does not include any fence 112 of the previous embodiment, but includes a mask layer 212, where the mask layer 212 is disposed on the surface S11 of the supporting board 111 and has a plurality of openings 212h above the surface S11.

The openings 212h partially expose the surface S11 of the supporting board 111, while the openings 212h and the supporting board 111 define a plurality of accommodation recesses R21. Specifically, each opening 212h and the part of the surface S11 form a sidewall SW2 and a bottom RB1 of one of the accommodation recesses R21 respectively, while the sidewall SW2 is equivalent to the sidewall of the opening 212h.

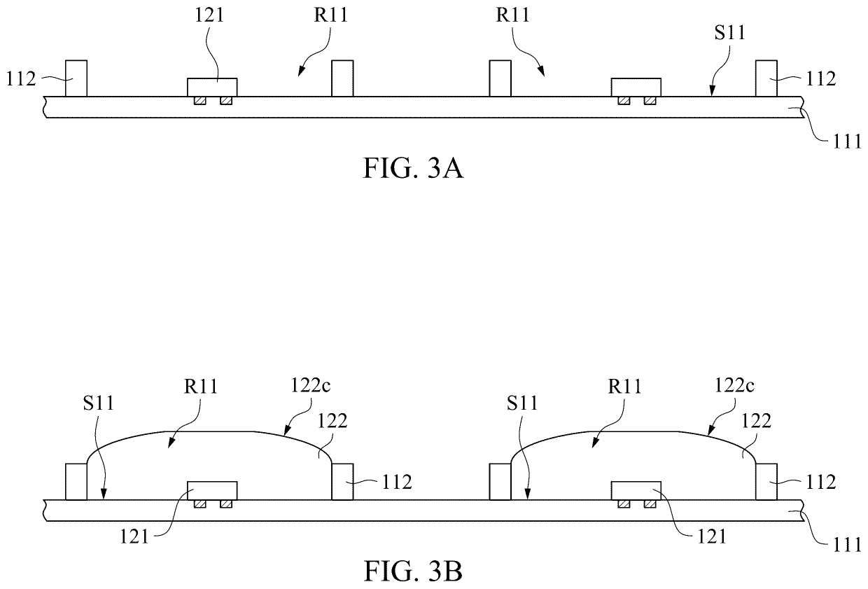

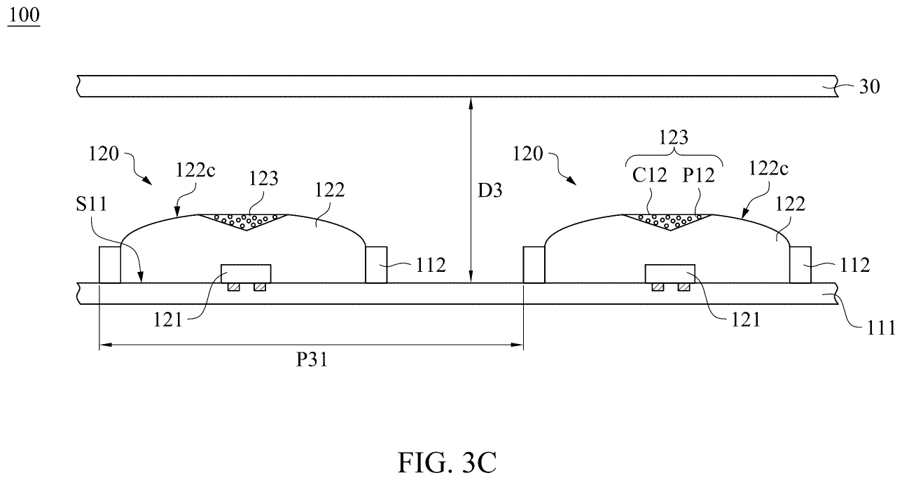

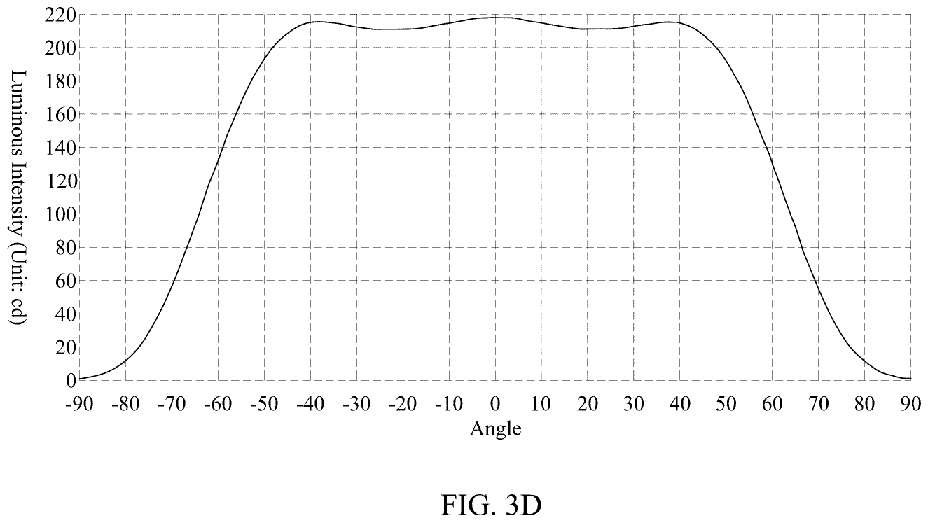

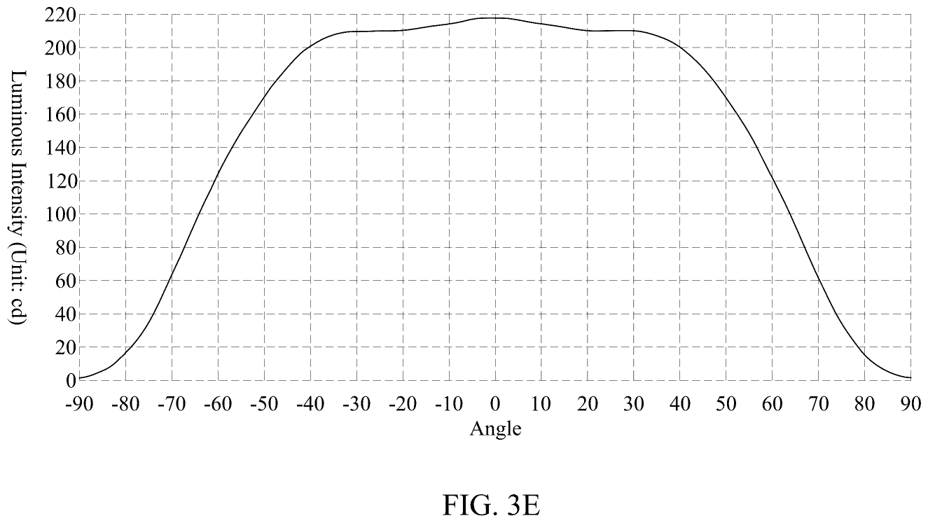

FIG. 3A to FIG. 3C are cross-sectional views of a method of manufacturing a light emitting device according to at least one embodiment of this disclosure, where FIG. 3A to FIG. 3C take the light emitting device 100 shown in FIG. 1A and FIG. 1B for example. It is emphasized that a person of ordinary skill in the art can manufacture the light emitting device 200 as shown in FIG. 2A and FIG. 2B according to the manufacturing method disclosed in FIG. 3A to FIG. 3C. Hence, the manufacturing method shown in FIG. 3A to FIG. 3C does not limit to the manufacture of light emitting device 100.

Referring to FIG. 3A, in the manufacturing method of this embodiment, first, a plurality of fences 112 and a plurality of dies 121 are disposed on the surface S11 of the supporting board 111, where the dies 121 can be mounted on the surface S11 of the supporting board 111 by flip chip. The order of disposing the dies 121 and the fences 112 is not limited. For example, the dies 121 may be disposed on the surface S11 before the fences 112. Alternatively, the dies 121 may be disposed on the surface S11 after the fences 112.

After the fences 112 are disposed on the surface S11, the fences 112 and the surface S11 will define a plurality of accommodation recesses R11, where the dies 121 are disposed in the accommodation recesses R11. In this embodiment, the dies 121 are disposed in the accommodation recesses R11 respectively, and there is one die 121 disposed in each of the accommodation recesses R11. However, in another embodiment, there may be two dies 121 disposed in each of the accommodation recesses R11, where the quantity of die 121 disposed in each accommodation recess R11 may be the same or different. Accordingly, the quantity of die 121 in each accommodation recess R11 is not limited by drawings (e.g., FIG. 3A and FIG. 3B).

Referring to FIG. 3B, afterwards, a plurality of wavelength converting colloids 122 are disposed in the accommodation recesses R11, where the wavelength converting colloids 122 cover the dies 121 and the parts of the surface S11 within the accommodation recesses R11. The wavelength converting colloids 122 can be formed by glue dispensing or molding. In this embodiment, the wavelength converting colloids 122 are formed by glue dispensing, where the wavelength converting colloid 122 has a convex surface 122c. In another embodiment, the wavelength converting colloids 122 are formed by molding, in which the wavelength converting colloids 122 can have various outer surfaces, such as the convex surface 122c, based on the inner structure of mold. Alternatively, the wavelength converting colloid 122 which is made by molding can be in the shape of a cube or a cylinder.

Referring to FIG. 3C, afterwards, a plurality of rooflike optic components 123 are disposed on the wavelength converting colloid 122, where the rooflike optic components 123 can be formed by molding. So far, a light emitting device 100 including the plurality of light emitting components 120 is basically complete. In this embodiment, the wavelength converting colloid 122 which is formed by glue dispensing is necessary to cure. The wavelength converting colloid 122 which cures incompletely is soft as a whole and has plasticity, while the rooflike optic component 123 is rigid as a whole, so that the rooflike optic component 123 can be disposed on the wavelength converting colloid 122 and embedded into the rooflike optic component 123. As a result, after the wavelength converting colloid 122 cures completely, the rooflike optic component 123 can be attached to the wavelength converting colloid 122.

It is necessary to note that since the wavelength converting colloid 122 can be formed by molding in another embodiment, the wavelength converting colloid 122 which is formed by molding can has a depression which is located directly above the die 121. Afterwards, a filling material and diffusing particles P12 can fill the depression, where the diffusing particles P12 are distributed in the filling material, and the filling material may be silicon. Afterwards, the filling material cures. After the filling material cures, the filling material becomes the pyramid C12, thereby forming the rooflike optic component 123.

In this embodiment, after the rooflike optic components 123 are disposed on the wavelength converting colloids 122, an optical film 30 can be disposed above the light emitting components 120, that is, the light emitting device 100 can further include the optical film 30. The optical film 30 may be a diffuser and can scatter the light emitted from the light emitting components 120, so as to cause the light emitting device 100 to emit light uniformly. In addition, a distance D3 between the optical film 30 and the surface S11 of the supporting board 111 is an optical distance (OD) of the light emitting device 100.

FIG. 3D and FIG. 3E depict rectangular candela distribution plots by simulating the light emitting device in FIG. 1B. The horizontal axis in FIG. 3D and FIG. 3E represents angles, while the vertical axis in FIG. 3D and FIG. 3E represents luminous intensity in candela (cd). The angle shown on the horizontal axis represents the light emitting angle of the die 121, wherein the zero degree on the horizontal axis means the luminous intensity measured in a direction perpendicular to the upper surface of the die 121. In addition, the angular range labeled on the horizontal axis includes positive values and negative values. The positive values and the negative values represent the light emitting angles respectively tilting in two directions opposite to each other. Taking FIG. 3C for example, positive angular range may mean measuring the luminous intensity of the light tilting to the right, while negative angular range may mean measuring the luminous intensity of the light tilting to the left.

Referring to FIG. 3C and FIG. 3D, FIG. 3D simulates the distribution of the luminous intensity of four light emitting components 120 arranged in a 2×2 matrix in the light emitting device 100 under the condition that the OD (i.e., the distance D3 as shown in FIG. 3) is 5 mm, and the pitch P31 (labeled in FIG. 3C) between adjacent two light emitting components 120 is 7 mm. According to the distribution of the luminous intensity depicted in FIG. 3D, the four light emitting components 120 arranged in a 2×2 matrix may have optical uniformity of 96.59%.

FIG. 3E simulates the distribution of the luminous intensity of four light emitting components 120 arranged in a 2×2 matrix in the light emitting device 100 under the condition that the OD is 5 mm, and the pitch P31 between adjacent two light emitting components 120 is 10 mm. According to the distribution of the luminous intensity depicted in FIG. 3E, the four light emitting components 120 arranged in a 2×2 matrix may have optical uniformity of 96.95%. It can be understood from FIG. 3D and FIG. 3E that the rooflike optic component 123 can help the light emitting device 100 to emit light uniformly indeed, so that the light emitting device 100 can achieve good optical uniformity.

Moreover, although FIG. 3A to FIG. 3C disclose the manufacturing method of the light emitting device 100, the manufacturing methods of the light emitting devices 200 and 100 are similar. The difference between the light emitting devices 200 and 100 is only that: the formation of the substrate 210 in the light emitting device 200 is different from the formation of the substrate 110 in the light emitting device 100.

Referring to FIG. 2B, since the substrate 210 includes the supporting board 111 and the mask layer 212, the mask layer 212 and the dies 121 may be disposed on the surface S11 of the supporting board 111 before disposing the wavelength converting colloid 122. The openings 212h of the mask layer 212 and the surface S11 can define the accommodation recesses R21 for disposing the dies 121. The order of the formations of the dies 121 and the mask layer 212 is not limited. For example, the dies 121 can be formed on the surface S11 before the mask layer 212. Alternatively, the dies 121 can be formed after the mask layer 212.

It is worth mentioning that in this embodiment, the dies 121 are disposed in the accommodation recesses R21 respectively, where there is one die 121 disposed in each of the accommodation recesses R21. However, in another embodiment, there may be at least two dies 121 disposed in each of the accommodation recesses R21, where the quantity of die 121 disposed in each accommodation recess R21 may be the same or different. Accordingly, the quantity of die 121 in each accommodation recess R21 is not limited by drawings.

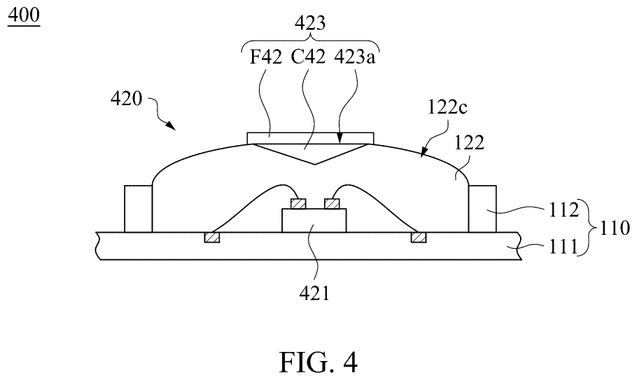

FIG. 4 is a top view of a light emitting device according to another embodiment of this disclosure. Referring to FIG. 4, a light emitting device 400 in this embodiment shown in FIG. 4 is similar to the light emitting device 100 in the previous embodiment. The light emitting devices 400 and 100 also include the same elements, such as the substrate 110 and the wavelength converting colloid 122, and have the same effectiveness. The manufacturing methods of the light emitting devices 400 and 100 are substantially the same, as shown in FIG. 3A to FIG. 3B. The following description will mainly describe the differences between the light emitting devices 100 and 400, while the same features of the light emitting devices 100 and 400 will not be repeated basically.

The light emitting device 400 includes a plurality of light emitting components 420, while the light emitting components 420 have a wavelength converting colloid 122, a die 421, and a rooflike optic component 423 apiece. The die 421 may be a LED, such as μLED or mini-LED, and can emit blue light or UV light. In addition, the die 421 may be a horizontal LED, that is, the electrodes of the die 421 are located at the same side of the die 421, as shown in FIG. 4.

Unlike the previous light emitting device 100, the die 421 is disposed on the supporting board 111 of the substrate 110 by wire-bonding. Furthermore, the rooflike optic component 423 includes a pyramid C42 and a reflective layer F42, where the compositions of the pyramids C42 and C12 are the same, and the reflective layer F42 covers the base 423a of the pyramid C42.

The reflective layer F42 may be white in appearance, and the reflective layer F42 may be made of ink or paint, where the reflective layer F42 can be formed by brush coating or ink-jet. That is, the reflective layer F42 may be a coating disposed on the outer surface (e.g., convex surface 122c) of the wavelength converting colloid 122, and the wavelength converting colloid 122 may be located between the reflective layer F42 and the substrate 110. Particularly, the wavelength converting colloid 122 may be located between the reflective layer F42 and the supporting board 111. The reflectivity of the reflective layer F42 at the wavelength of 480 nm may range between 85% and 99%, so that the rooflike optic component 423 can reflect the light of the die 421 and attenuate a large amount of light emitted from the upper surface of the die 421, thereby helping the light emitting device 400 to emit light uniformly.

It is necessary to note that in another embodiment, the rooflike optic component 423 can include only reflective layer F42. That is, the rooflike optic component 423 can be the reflective layer F42, where the reflective layer F42 can directly cover the wavelength converting colloid 122. For example, the reflective layer F42 can be ink or paint on the outer surface (e.g., convex surface 122c) of the wavelength converting colloid 122 by directly brush coating or ink-jet. Hence, the pyramid C42 depicted in FIG. 4 can be omitted.

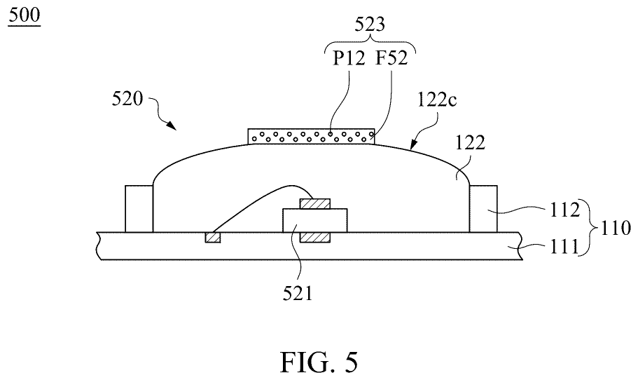

FIG. 5 is a top view of a light emitting device according to another embodiment of this disclosure. Referring to FIG. 5, a light emitting device 500 of the embodiment shown in FIG. 5 is similar to the light emitting device 400 of the previous embodiment, where the light emitting devices 500 and 400 have the same effectiveness and include the same elements, such as the substrate 110 and the wavelength converting colloid 122. The following description will mainly describe the differences between the light emitting devices 500 and 400, while the same features of the light emitting devices 500 and 400 will not be repeated basically.

The light emitting device 500 includes a plurality of light emitting components 520, where the light emitting components 520 include a wavelength converting colloid 122, a die 521, and a rooflike optic component 523 apiece. The die 521 is disposed on the supporting board 111 of the substrate 110 by wire-bonding. In addition, the die 521 may be a LED, such as μLED or mini-LED, and can emit blue light or UV light.

In contrast to the light emitting device 400, the die 521 is a vertical LED, that is, the electrodes of the die 521 are respectively located at two sides of the die 521 opposite to each other. As shown in FIG. 5, there are two electrodes located at the upper side and the lower side of the die 521 respectively. The lower electrode is connected to the supporting board 111, and the upper electrode is connected to a bonding wire. Furthermore, the rooflike optic component 523 includes a coating F52 and a plurality of diffusing particles P12. The coating F52 may be located on the outer surface (e.g., convex surface 122c) of the wavelength converting colloid 122. In other words, the coating F52 may directly cover the outer surface of the wavelength converting colloid 122. Moreover, the wavelength converting colloid 122 may be located between the coating F52 and the substrate 110. Particularly, the wavelength converting colloid 122 may be located between the coating F52 and the supporting board 111. The diffusing particles P12 are distributed in the coating F52, and the coating F52 partially covers the wavelength converting colloid 122. In addition, the coating F52 may be made of silicone.

It is worth mentioning that the die 521 in FIG. 5 can be replaced by the die 421 in FIG. 4, and the die 421 in FIG. 4 can be replaced by the die 521 in FIG. 5, that is, any one of the dies 421 and 521 can be employed in the light emitting devices 400 and 500. In addition, in the embodiments as shown in FIG. 4 and FIG. 5, the light emitting devices 400 and 500 include the substrate 110. However, in another embodiment, the substrate 110 as depicted in FIG. 4 and FIG. 5 can be replaced by the substrate 210 as depicted in FIG. 2B. That is, the substrate 210 in FIG. 2B can be used in the light emitting devices 400 and 500 in FIG. 4 and FIG. 5.

In addition, in FIG. 4 and FIG. 5, the dies 421 and 521 are disposed on the substrate 110 by wire-bonding. However, in another embodiment, the dies 421 and 521 in the light emitting devices 400 and 500 can be replaced by the die 121 which is disposed on the substrate 110 by flip chip, so the dies 121 in FIG. 1B and FIG. 2B can be used in the light emitting devices 400 and 500 in FIG. 4 and FIG. 5. Likewise, the die 121 in FIG. 1B and FIG. 2B can be replaced by the dies 421 or 521, that is, the dies 421 and 521 in FIG. 4 and FIG. 5 also can be used in the light emitting devices 100 and 200 in FIG. 1B and FIG. 2B.

Consequently, sine the above rooflike optic component can attenuate a large amount of light emitted from the upper surface of the die 121, so the rooflike optic component can help the light emitting device to emit light uniformly. As a result, the light emitting devices disclosed in the previous embodiments are capable of being employed for the backlight module used in LCD, so as to preserve or improve the image quality displayed by the LCD.

Although the present application has been disclosed in various embodiments as above, it is not intended to limit the present application and any person with common knowledge in the field of technology may make some changes and embellishments without departing from the spirit and scope of this application, and therefore the scope of protection of this application shall be subject to the scope of the patents applied for, as defined in the appended patent application.

What is claimed is:

1. A light emitting device, comprising:
a substrate, having a surface and a plurality of accommodation recesses in the surface;
a plurality of light emitting components, disposed in the accommodation recesses, wherein each of the light emitting components comprises:
a die, disposed on the substrate and located in one of the accommodation recesses, wherein the die is perpendicularly projected onto the substrate to form a first orthogonal projection region and used for emitting light;
a wavelength converting colloid, disposed on the substrate, filling one of the accommodation recesses, and covering the die, wherein the wavelength converting colloid has a convex surface; and
a rooflike optic component, disposed on the convex surface of the wavelength converting colloid and overlapping the die, wherein the rooflike optic component is perpendicularly projected onto the substrate to form a second orthogonal projection region, and a size of the first orthogonal projection region of the die is smaller than a size of the second orthogonal projection region of the rooflike optic component.

2. The light emitting device of claim 1, wherein a reflectivity of the rooflike optic component at a wavelength of 480 nm ranges between 70% and 99%.

3. The light emitting device of claim 1, wherein the rooflike optic component comprises:
a pyramid, having an apex and a base opposite to the apex, wherein the base has an edge, and a distance between the pyramid and the surface of the substrate increases gradually from the apex to the edge.

4. The light emitting device of claim 3, wherein the rooflike optic component comprises a plurality of diffusing particles, and the diffusing particles are distributed in the pyramid.

5. The light emitting device of claim 3, wherein the rooflike optic component further comprises a reflective layer, and the reflective layer covers the base of the pyramid.

6. The light emitting device of claim 1, wherein the rooflike optic component comprises a coating, and the coating partially covers the wavelength converting colloid.

7. The light emitting device of claim 6, wherein the rooflike optic component further comprises a plurality of diffusing particles, and the diffusing particles are distributed in the coating.

8. The light emitting device of claim 1, wherein the substrate comprises:
a supporting board, having the surface; and
a plurality of fences, disposed on the surface, wherein the fences and the supporting board define the accommodation recesses, and the surface of the substrate and each of the fences form a bottom and a sidewall of one of the accommodation recesses respectively.

9. The light emitting device of claim 1, wherein the substrate comprises:
a supporting board, having the surface; and
a mask layer, disposed on the surface, and having a plurality of openings above the surface, wherein the openings and the supporting board define the accommodation recesses, and a part of the surface of the substrate and each of the openings form a bottom and a sidewall of one of the accommodation recesses respectively.

10. The light emitting device of claim 1, wherein a ratio of a width of the wavelength converting colloid to a length of the rooflike optic component is from 1.72 to 3.5.

11. A light emitting device, comprising:
a substrate, having a surface and a plurality of accommodation recesses in the surface;
a plurality of light emitting components, disposed in the accommodation recesses, wherein each of the light emitting components comprises:
a die, disposed on the substrate and located in one of the accommodation recesses, wherein the die is perpendicularly projected onto the substrate to form a first orthogonal projection region and used for emitting light;
a wavelength converting colloid, disposed on the substrate, filling one of the accommodation recesses, and covering the die, wherein the wavelength converting colloid has a convex surface; and
a rooflike optic component, disposed on the convex surface of the wavelength converting colloid and overlapping the die, wherein the rooflike optic component comprises a coating disposed on the convex surface of the wavelength converting colloid, wherein the wavelength converting colloid is located between the coating and the substrate;
the rooflike optic component is perpendicularly projected onto the substrate to form a second orthogonal projection region; and
a size of the first orthogonal projection region of the die is smaller than a size of the second orthogonal projection region of the rooflike optic component.

12. The light emitting device of claim 11, wherein a reflectivity of the rooflike optic component at a wavelength of 480 nm ranges between 70% and 99%.

13. The light emitting device of claim 11, wherein the coating partially covers the wavelength converting colloid.

14. The light emitting device of claim 11, wherein the rooflike optic component further comprises a plurality of diffusing particles, and the diffusing particles are distributed in the coating.

15. The light emitting device of claim 11, wherein the rooflike optic component further comprises:
a pyramid, having an apex and a base opposite to the apex, wherein the base has an edge, and a distance between the pyramid and the surface of the substrate increases gradually from the apex to the edge.

16. The light emitting device of claim 15 wherein the rooflike optic component comprises a plurality of diffusing particles, and the diffusing particles are distributed in the pyramid.

17. The light emitting device of claim 11, wherein the substrate comprises:
a supporting board, having the surface; and
a plurality of fences, disposed on the surface, wherein the fences and the supporting board define the accommodation recesses, and the surface of the substrate and each of the fences form a bottom and a sidewall of one of the accommodation recesses respectively.

18. The light emitting device of claim 11, wherein the substrate comprises:
a supporting board, having the surface; and
a mask layer, disposed on the surface, and having a plurality of openings above the surface, wherein the openings and the supporting board define the accommodation recesses, and a part of the surface of the substrate and each of the openings form a bottom and a sidewall of one of the accommodation recesses respectively.

19. The light emitting device of claim 11, wherein a ratio of a width of the wavelength converting colloid to a length of the rooflike optic component is from 1.72 to 3.5.
